(19) United States
(12) Patent Application Publication
(10) Pub. No.: US 2010/0177231 A1
(43) Pub. Date: Jul. 15, 2010

(54) SOLID-STATE IMAGE CAPTURING APPARATUS, METHOD FOR MANUFACTURING THE SAME, AND ELECTRONIC INFORMATION DEVICE

(75) Inventor: Takahiro Tsuchida, Osaka (JP)

Correspondence Address: EDWARDS ANGELL PALMER & DODGE LLP, P.O. BOX 55874, BOSTON, MA, 02205, US

(73) Assignee: SHARP KABUSHIKI KAISHA, Osaka (JP)

(21) Appl. No.: 12/516,448

(22) PCT Filed: Nov. 21, 2007
(86) PCT No.: PCT/JP2007/072595

§ 371 Date: Dec. 11, 2009

(30) Foreign Application Priority Data
Nov. 30, 2006 (JP) 2006-324943

(51) Int. Cl. H04N 5/335; H01L 31/14; H01L 31/18; H01L 31/0248

(52) U.S. Cl. 348/308; 438/60; 438/87; 438/72; 348/E05.091; 257/E31.01; 257/E31.097; 257/E31.002

(57) ABSTRACT

A solid-state image capturing apparatus is manufactured, which has a high sensitivity and high resolution with no color filter or no on-chip microlens required and with no shading generated or no variance in performance between pixel sections. In a solid-state image capturing apparatus 1, a plurality of pixel sections 2 (solid-state image capturing devices), each having light receiving sections 21 to 23 laminated in a depth direction of a semiconductor substrate 3, is repeatedly arranged according to a sequence in a direction along a plane of the semiconductor substrate 3. For incident light, electromagnetic waves having wavelength bands corresponding to the depths of the respective light receiving sections 21 to 23 are detected at the light receiving sections 21 to 23 in accordance with the wavelength dependency of optical absorption coefficient of semiconductor substrate material, and signal charges are generated. The pixel sections 2 are electrically separated from each other by pixel separation section diffusion layers 4. Wiring layers 71 to 73, which forms transfer paths for transferring signal charges from the light receiving sections 21 to 23, and the required number of transistors 5 are provided on the surface of the semiconductor substrate 3, which is the opposite side of the electromagnetic wave incidence side.

### TECHNICAL FIELD

The present invention relates to: a solid-state image capturing apparatus method for manufacturing a solid-state image capturing apparatus (e.g., CMOS image sensor, CCD image sensor and the like), in particular, a solid-state image capturing apparatus using a process of separating and detecting light (electromagnetic wave) having different wavelengths by using a plurality of light receiving sections that are laminated in a depth direction of a semiconductor substrate; a solid-state image capturing apparatus manufactured using the solid-state image capturing apparatus manufacturing method; and an electronic information device (e.g., digital camera (digital video camera, digital still camera), a variety of image input cameras, scanner, facsimile, cell phone device equipped with camera and the like) using the solid-state image capturing apparatus as an image input device for an image capturing section thereof.

### BACKGROUND ART

For example, in a conventional color solid-state image capturing apparatus represented by a CMOS image sensor, a CCD image sensor or the like, a plurality of light receiving sections (a plurality of pixel sections) is arranged in a matrix on a plurality of solid-state image capturing devices, wherein each of the plurality of light receiving sections performs a photoelectric conversion on incident light so as to generate a signal charge. Three or four types of color filters are arranged in a mosaic so as to correspond to the respective light receiving sections. With this structure, a color signal corresponding to each color filter is output from a pixel section, and a computational process is performed on color signals so as to generate color image data. Generally, four pixel sections (light receiving sections) corresponding to one red (R) light, two green (G) lights and one blue (B) light are repeatedly arranged in a plane.

It is necessary to electrically separate the light receiving sections described above from each other, and various methods have been previously proposed to separate light receiving sections from each other. As shown in FIG. 9, Reference 1, for example, proposes a solid-state image capturing apparatus 100 using a process of separating light receiving sections (pixel sections) from each other by performing an ion implantation and forming a pixel separation diffusion layer (referred to as P+ guard layer 104) between light receiving sections, in each of which an N region 102 and a surface P+ layer 103 are provided over a P well layer 101 in this order.

However, in a conventional color solid-state image capturing apparatus having color filters arranged in a mosaic thereon, about ⅔ of the incident light is absorbed by color filters of three primary colors, for example. Accordingly, in fact, only the about ⅓ remaining incident light can be used for outputting a color signal, thus causing problems of low light utilization efficiency and low sensitivity. In addition, a color signal of only one color can be obtained at each pixel section, and also the signal of each of three primary colors is detected at a different location, thus causing problems of low resolution and false color being easily produced.

In order to address the problems described above, Reference 2 and Reference 3 disclose a solid-state image capturing apparatus that uses a process of performing a color separation by laminating a plurality of light receiving sections corresponding to the respective colors in a depth direction of a semiconductor substrate, utilizing a wavelength dependency of optical absorption coefficient of silicon forming the semiconductor substrate and detecting light having wavelength bands corresponding to depths of the respective light receiving sections.

The conventional solid-state image capturing apparatus disclosed in Reference 2 and Reference 3, for example, has a cross-sectional structure of a pixel section such that photodiodes for generating signal charges for blue light, green light and red light are laminated in this order from the surface of the pixel section on the light incidence side. According to the conventional solid-state image apparatus, the color separation of each pixel is performed by utilizing the wavelength dependency of optical absorption coefficient of silicon. Thus, there is no need for providing a color filter, and much of the incident light is photoelectrically converted to become signal charge. Hence, the light utilization efficiency is approximately 100%, and a signal of each of the three primary colors is obtained at the corresponding depth of each pixel section. Therefore, it is possible to generate excellent color image data having a high sensitivity and high resolution without false color. In other words, in the conventional solid-state image capturing apparatus, four pixel sections (light receiving sections) corresponding to one red (R) light, two green (G) lights and one blue (B) light were repeatedly arranged in a plane. However, according to this conventional solid-state image apparatus, light receiving sections corresponding to the three primary colors of R, G and B are vertically stacked, so that they can be used as one pixel section. Thus, it is possible to obtain a resolution four times as high as conventionally obtained. In addition, according to the conventional solid-state image capturing apparatus using this process, there is no need for providing a color filter. Thus, it is possible to significantly simplify a manufacturing step.

Further, Reference 4, for example, proposes a bottom-surface-irradiation type solid-state image capturing device in which photodiodes (light receiving sections) are arranged in a direction along the top surface of a substrate, multi-layered wiring layers are formed on the photodiodes, and light is irradiated upon the photodiodes from the bottom surface side of the substrate, which is located on the opposite side of the multi-layered wiring layers with respect to the substrate. With this structure, since light is not deflected by wiring layers, it is possible to ease a layout restriction due to the wiring layers.

Reference 1: Japanese Laid-Open Publication No. 2006-24907

Reference 2: Specification of United States Patent No. 5965875

Reference 3: Japanese Laid-Open Publication No. 2005-303266

Reference 4: Japanese Laid-Open Publication No. 2005-150463

### DISCLOSURE OF THE INVENTION

However, the conventional solid-state image capturing apparatus disclosed in Reference 1 has the following problems.

As describe above, in the conventional solid-state image capturing apparatus disclosed in Reference 1, four light receiving sections corresponding to one red (R) light, two green (G) lights and one blue (B) light are arranged in a plane, and a control transistor for controlling the transfer of signal charge is arranged in a plane at a location different from those of the light receiving sections. Therefore, it is difficult to enhance the degree of integration in a pixel. Further, since the light receiving sections and the control transistor are arranged in a plane, it is necessary to provide a photolithography step and an ion implantation step of forming a diffusion layer that forms a light receiving section, and a photolithography step and an ion implantation step of forming a pixel separation diffusion layer (which corresponds to the P+ guard layer 104 in Reference 1). As such, the alignment precision between the light receiving section diffusion layer and the pixel separation diffusion layer deteriorates, which becomes a cause of variance in performance between pixel sections.

In addition, as shown in FIG. 9, in the conventional solid-state image capturing apparatus disclosed in Reference 1, multi-layered wiring layer 105 functioning as a transfer path are provided on the same side as the light incidence side of a semiconductor substrate 106, wherein the multi-layered wiring layers are provided to transfer signal charges output from pixel sections. As such, in order to focus the light upon a light receiving section, it is necessary to arrange the wiring layer 105 at a location where the wiring layer 105 is not provided directly above the light receiving section. In other words, the location where the wiring layer 105 can be provided is extremely limited. Thus, it is difficult to enhance the degree of integration in a pixel. Further, the more multi-layered wiring layer 105 becomes, the deeper the light receiving sections are located from the light incidence surface. In particular, in order to prevent light that is incident from an oblique direction from being deflected by the wiring layer 105 in a light path, it is necessary to form on-chip microlenses on the wiring layer 105 so as to focus the light upon the light receiving sections in an efficient manner. Therefore, in the conventional solid-state image capturing apparatus 100 disclosed in Reference 1, it is necessary to provide a color-filter forming step and an on-chip microlens forming step in a manufacturing process associated with the optical characteristic that is specific to the solid-state image capturing apparatus 100. Accordingly, a manufacturing step becomes complicated, thus reducing the yield.

In addition, the conventional solid-state image capturing apparatus disclosed in Reference 2 has the following problems.

As in the case of Reference 1, in the conventional solid-state image capturing apparatus disclosed in Reference 2, a multi-layered wiring layer is provided on the same surface side as the light incidence side of a semiconductor substrate, wherein the multi-layered wiring layer is required in order to transfer signal charges output from pixel sections. As such, the more multi-layered wiring layer becomes in a pixel array, the deeper the light receiving sections are located from the light incidence side. In particular, in order to prevent light that is incident from an oblique direction from being deflected by the wiring layers in a light path, it is necessary to form on-chip microlenses on the wiring layer so as to focus the light upon the light receiving sections in an efficient manner. Therefore, in the conventional solid-state image capturing apparatus disclosed in Reference 2, among a color-filter forming step and an on-chip microlens forming step in a manufacturing process associated with the optical characteristic that is specific to a solid-state image capturing apparatus, it is possible to eliminate the color-filter forming step, yet it is not possible to eliminate the on-chip microlens forming step. In addition, it is preferable that a semiconductor manufacturing apparatus can be diverted for manufacturing another semiconductor device. Therefore, if a forming step (e.g., on-chip microlens forming step) that is specific to a solid-state image capturing apparatus is required, this causes a problem of low efficiency in manufacturing a solid-state image capturing apparatus with the same line that is used for another semiconductor device. Further, in the case where another semiconductor device and a solid-state image capturing apparatus are mounted in the same chip module in a mixed manner, if there is, for example, an on-chip microlens forming step, this causes a problem of high functionality of the conventional solid-state image capturing apparatus being challenging to incorporate since the conformity with other steps is low and the degree of difficulty in development is high.

In addition, even if the conventional solid-state image capturing apparatus disclosed in Reference 2 includes an on-chip microlens, the light focusing efficiency is significantly decreased due to the deflection of light in a light path as wiring layers become more multi-layered. Therefore, there is an upper-limit for the number of wiring layers to be laminated. In actuality, the upper-limit is four or five layers. Thus, it is not possible to incorporate a circuit that requires multi-layered wirings of more than four or five into a solid-state image capturing apparatus. Therefore, in the conventional solid-state image capturing apparatus disclosed in Reference 2, even if a high sensitivity and a high resolution are achieved without increasing the size of the chip, it is not possible to implement the down-scaling of an entire chip module set since a high functionality image computational process circuit or the like cannot be mounted on the same module chip.

Furthermore, in the conventional solid-state image capturing apparatus disclosed in Reference 2, it is necessary to provide a wiring layer between pixel sections in order to transfer a signal charge output from a pixel section. The resolution of a solid-state image capturing apparatus is decreased due to an area size required for a wiring width and a wiring arrangement accordingly. Particularly, in a CMOS image sensor, it is necessary to arrange a plurality of types of transistors in a pixel array in order to amplify a signal charge from a pixel section and to transfer the signal charge. Also, minimizing these transistors to the smallest as possible is demanded without the decrease of resolution. However, along with the miniaturization of transistors, a structural variation associated with the formation of the transistors increases. As a result, the signal charge amplification characteristic resulting from the structural variation is different at each pixel section, thus causing a problem of reducing the image quality. The situation is similar in the conventional solid-state image capturing apparatus disclosed in Reference 2. The more the stability of transistor characteristic in a pixel section is demanded, the more the resolution decreases or the more the image quality deteriorates.

Further, although Reference 3 describes that photoelectric conversion sections corresponding to respective colors are laminated in a depth direction and MOS circuits corresponding to the respective photoelectric conversion sections are provided on the opposite side of a light incidence side, it does not mention pixel separation. Moreover, unlike the present invention, Reference 3 does not describe how to improve the alignment precision between a light receiving section diffusion layer and a pixel separation diffusion layer or describe how to reduce the variance in performance between pixel sections.

Further, the conventional solid-state image capturing apparatus disclosed in Reference 4 has the following problems.

In the conventional solid-state image capturing apparatus disclosed in Reference 4, a wiring layer is provided below a photodiode irradiated upon by light. Therefore, it is possible to significantly ease a layout restriction due to the wiring layer since light is not deflected by the wiring layer, as happens in the conventional solid-state image capturing apparatus disclosed in Reference 3, yet it is necessary to form a planarization film on the light receiving section in order to form a color filter. As a result, the location where the photodiode is arranged is extremely deep when it is viewed from the light incidence side. Thus, the incidence angle of light is increased at a peripheral portion of an image capturing region. As such, it is necessary to bend the incident light at the peripheral portion of the image capturing region for excellent focus upon a light receiving section. This results in the requirement of on-chip microlens. Accordingly, even in the conventional solid-state image capturing apparatus disclosed in Reference 4, a similar problem to the one described with reference to Reference 2 occurs.

The present invention is intended to solve the conventional problems described above. The objective of the present invention is to provide: a solid-state image capturing apparatus manufacturing method capable of significantly reducing the variance in performance between pixel sections with a simplified manufacturing step with no planarization film forming step, no color filter forming step or no on-chip microlens forming step required; a solid-state image capturing apparatus that is manufactured using the solid-state image capturing apparatus manufacturing method and that has a high sensitivity and high resolution with no color filter or no on-chip microlens required and with no shading generated; and an electronic information device using the solid-state image capturing apparatus as an image input device for an image capturing section thereof.

A solid-state image capturing apparatus manufacturing method according to the present invention includes: a light receiving section forming step of forming a plurality of impurity diffusion layers laminated in a depth direction of a semiconductor substrate as a plurality of light receiving sections by performing a plurality of ion implantations on an entire predetermined region of the semiconductor substrate; a pixel separation section forming step of forming impurity diffusion layers for pixel separation in the predetermined region to separate pixel sections; and a transfer path forming step of forming transfer paths for transferring signal charges from the plurality of light receiving sections, the transfer paths being formed on an opposite side of an electromagnetic wave incidence side where an electromagnetic wave is incident upon the plurality of light receiving sections, thereby the objective described above being achieved.

Preferably, in a solid-state image capturing apparatus manufacturing method according to the present invention, the entire predetermined region of the semiconductor substrate is an entire semiconductor substrate or an entire image capturing region of the semiconductor substrate.

Still preferably, in a solid-state image capturing apparatus manufacturing method according to the present invention, the pixel separation section forming step includes: a mask forming step of forming an ion implantation mask having an opening at a location corresponding to a pixel separation section in the semiconductor substrate; and an ion implantation step of performing an ion implantation for the semiconductor substrate via the opening of the ion implantation mask.

Still preferably, in a solid-state image capturing apparatus manufacturing method according to the present invention, the mask forming step is a photolithography step.

Still preferably, in a solid-state image capturing apparatus manufacturing method according to the present invention, an ion implantation is performed from a surface of an opposite side of a side surface where the transfer paths are formed at at least one of the light receiving section forming step and the pixel separation section forming step.

Still preferably, in a solid-state image capturing apparatus manufacturing method according to the present invention, an ion implantation is performed from a side surface where the transfer paths are formed at at least one of the light receiving section forming step and the pixel separation section forming step.

Still preferably, in a solid-state image capturing apparatus manufacturing method according to the present invention, the semiconductor substrate is a silicon substrate having an epitaxial layer thereon.

Still preferably, in a solid-state image capturing apparatus manufacturing method according to the present invention, the light receiving section forming step forms photodiodes as the plurality of light receiving sections, each of the photodiodes being formed due to a semiconductor junction having different conductive types from each other.

Still preferably, in a solid-state image capturing apparatus manufacturing method according to the present invention, the light receiving section forming step forms an N number of light receiving sections used as the plurality of light receiving sections, wherein the N number of light receiving sections include a first light receiving section for detecting an electromagnetic wave having a first wavelength band up to an Nth light receiving section for detecting an electromagnetic wave having an Nth wavelength band, where N is a natural number greater than or equal to 2.

Still preferably, in a solid-state image capturing apparatus manufacturing method according to the present invention, the light receiving section forming step forms a first light receiving section for detecting an electromagnetic wave having a first wavelength band and a second light receiving section for detecting an electromagnetic wave having a second wavelength band used as the plurality of light receiving sections.

Still preferably, in a solid-state image capturing apparatus manufacturing method according to the present invention, the light receiving section forming step forms a first light receiving section for detecting an electromagnetic wave having a first wavelength band, a second light receiving section for detecting an electromagnetic wave having a second wavelength band, and a third light receiving section for detecting an electromagnetic wave having a third wavelength band used as the plurality of light receiving sections.

Still preferably, in a solid-state image capturing apparatus manufacturing method according to the present invention, the light receiving section forming step forms a first light receiving section for detecting an electromagnetic wave having a first wavelength band, a second light receiving section for detecting an electromagnetic wave having a second wavelength band, a third light receiving section for detecting an electromagnetic wave having a third wavelength band, and a fourth light receiving section for detecting an electromagnetic wave having a fourth wavelength band used as the plurality of light receiving sections.

Still preferably, in a solid-state image capturing apparatus manufacturing method according to the present invention, the light receiving section forming step forms the first light receiving section to detect white light when a depth of the first light receiving section from the surface of the semiconductor substrate on a light incidence side is in a range between 0.2 μm (including 0.2 μm) and 2.0 μm (including 2.0 μm) at a depletion layer, and forms the second light receiving section to detect infrared light when a depth of the second light receiving section from the surface of the semiconductor substrate on the light incidence side is in a range of 3.0 μm±0.3 μm.

Still preferably, in a solid-state image capturing apparatus manufacturing method according to the present invention, the light receiving section forming step forms the first light receiving section to detect ultraviolet light when a depth of the first light receiving section from the surface of the semiconductor substrate on a light incidence side is in a range between 0.1 μm (including 0.1 μm) and 0.2 μm (including 0.2 μm), and the second light receiving section to detect white light when a depth of the second light receiving section from the surface of the semiconductor substrate on the light incidence side is in a range 0.2 μm (including 0.2 μm) and 2.0 μm (including 2.0 μm) at a depletion layer.

Still preferably, in a solid-state image capturing apparatus manufacturing method according to the present invention, the light receiving section forming step forms the first light receiving section, the second light receiving section and the third light receiving section to detect three primary colors, respectively, in which blue light is detected when a depth of the first light receiving section from the surface of the semiconductor substrate on a light incidence side is in a range between 0.1 μm (including 0.1 μm) and 0.4 μm (including 0.4 μm), green light is detected when a depth of the second light receiving section from the surface of the semiconductor substrate on the light incidence side is in a range between 0.4 μm (including 0.4 μm) and 0.8 μm (including 0.8 μm), and red light is detected when a depth of the third light receiving section from the surface of the semiconductor substrate on the light incidence side is in a range between 0.8 μm (including 0.8 μm) and 2.5 μm (including 2.5 μm).

Still preferably, in a solid-state image capturing apparatus manufacturing method according to the present invention, the light receiving section forming step forms the first light receiving section, the second light receiving section, the third light receiving section and the fourth light receiving section to detect three primary colors and emerald color, respectively, in which blue light is detected when a depth of the first light receiving section from the surface of the semiconductor substrate on a light incidence side is in a range between 0.1 μmm (including 0.1 μm) and 0.4 μm (including 0.4 μm), emerald light is detected when a depth of the second light receiving section from the surface of the semiconductor substrate on the light incidence side is in a range between 0.3 μm (including 0.3 μm) and 0.6 μm (including 0.6 μm), green light is detected when a depth of the third light receiving section from the surface of the semiconductor substrate on the light incidence side is in a range between 0.4 μm (including 0.4 μm) and 0.8 μm (including 0.8 μm), and red light is detected when a depth of the fourth light receiving section from the surface of the semiconductor substrate on the light incidence side is in a range between 0.8 μm (including 0.8 μm) and 2.5 μm (including 2.5 μm).

Still preferably, in a solid-state image capturing apparatus manufacturing method according to the present invention, the light receiving section forming step forms a further light receiving section, in which a depth of the further light receiving section from the surface of the semiconductor substrate on the electromagnetic wave incidence side is set to a light receiving section depth corresponding to color light that is intended for accurate representation.

Still preferably, in a solid-state image capturing apparatus manufacturing method according to the present invention, the light receiving section is formed to have a flat surface.

Still preferably, in a solid-state image capturing apparatus manufacturing method according to the present invention, the pixel separation section forming step forms the impurity diffusion layers for pixel separation to have each a predetermined width provided in a lattice in a plane view.

Still preferably, in a solid-state image capturing apparatus manufacturing method according to the present invention, the pixel separation section forming step forms the impurity diffusion layers for pixel separation, each formed like a wall at a location deeper than the light receiving section that is provided at the deepest location from the surface of the semiconductor substrate on the electromagnetic wave incidence side.

Still preferably, in a solid-state image capturing apparatus manufacturing method according to the present invention, a length of one side of a pixel section surrounded by the impurity diffusion layers for pixel separation is within a range between 1.0 μm (including 1.0 μm) and 20.0 μm (including 20.0 μm) when viewed from the electromagnetic wave side.

Still preferably, in a solid-state image capturing apparatus manufacturing method according to the present invention, a pixel section has a squared or rectangular shape when viewed from the electromagnetic wave side.

Still preferably, in a solid-state image capturing apparatus manufacturing method according to the present invention, the number of solid-state image capturing devices, each corresponding to a single pixel section, to be effectively arranged is set in a range between 100,000 pixels (including 100,000 pixels) and 50 million pixels (including 50 million pixels).

Still preferably, in a solid-state image capturing apparatus manufacturing method according to the present invention, the transfer path forming step forms in each of the plurality of pixel sections: a circuit for selecting a light receiving section of a particular pixel section among the plurality of pixel sections and for outputting a signal from the selected light receiving section of the particular pixel section, and forms transistors that form the circuit on the opposite side of the semiconductor substrate on the electromagnetic wave incidence side.

Still preferably, in a solid-state image capturing apparatus manufacturing method according to the present invention, the transfer path forming step forms in each of the plurality of pixel sections: a circuit for selecting a light receiving section of a particular pixel section among the plurality of pixel sections and for outputting a signal from the selected light receiving section of the particular pixel section, and forms transistors that form the circuit in an impurity diffusion layer well forming the light receiving sections and on the impurity diffusion layer well.

Still preferably, in a solid-state image capturing apparatus manufacturing method according to the present invention, the transfer path forming step forms in each of the plurality of pixel sections: an amplification section for amplifying a signal in accordance with a signal voltage transferred from the light receiving section to a charge detection section, wherein the amplification section is configured with a transistor.

Still preferably, in a solid-state image capturing apparatus manufacturing method according to the present invention, the transfer path forming step forms in each of the plurality of pixel sections: a selection section capable of selecting a light receiving section in each pixel section by controlling the reading of the signal amplified by the amplification section; and a reset section for resetting the signal voltage at the charge detection section to a predetermined voltage, wherein the selection section and the reset section are each configured with a transistor.

Still preferably, in a solid-state image capturing apparatus manufacturing method according to the present invention, the transfer path forming step forms the transfer paths with transistors and wiring layers connected to the transistors.

Still preferably, in a solid-state image capturing apparatus manufacturing method according to the present invention, the transfer path forming step forms a contact section in an interlayer insulation film located between the light receiving section and the wiring layer to electrically connect the light receiving section and the wiring layer.

Still preferably, in a solid-state image capturing apparatus manufacturing method according to the present invention, the wiring layers form a multi-layered wiring layer, and the transfer path forming step forms a contact section in an interlayer insulation film located between the wiring layers to electrically connect the wiring layers.

Still preferably, the a solid-state image capturing apparatus manufacturing method according to the present invention further includes a polishing step of polishing the surface of the semiconductor substrate on the electromagnetic wave side to optimize a distance to each of the plurality of light receiving sections.

Still preferably, in a solid-state image capturing apparatus manufacturing method according to the present invention, the polishing step polishes the surface of the semiconductor substrate on the electromagnetic wave incidence side to a top surface of the light receiving section which is located closest to the surface of the semiconductor substrate on the electromagnetic wave incidence side.

Still preferably, a solid-state image capturing apparatus manufacturing method according to the present invention further includes an infrared cut filter forming step of forming an infrared cut filter on the surface of the semiconductor substrate on the electromagnetic wave incidence side.

Still preferably, in a solid-state image capturing apparatus manufacturing method according to the present invention further includes a support substrate attachment step of attaching a support substrate on the opposite side of the surface of the semiconductor substrate on the electromagnetic wave incidence side to enhance the durability of the semiconductor substrate.

Still preferably, in a solid-state image capturing apparatus manufacturing method according to the present invention, the support substrate is a transparent silicon substrate or a transparent glass substrate.

A solid-state image capturing apparatus according to the present invention is manufactured according to a solid-state image capturing apparatus manufacturing method according to the present invention describe above, thereby the objective described above being achieved.

Preferably, in a solid-state image capturing apparatus according to the present invention, a plurality of pixel sections, each having a plurality of light receiving sections laminated in a depth direction of a semiconductor substrate, are arranged according to a sequence in a direction along a plane of the semiconductor substrate; for incident electromagnetic wave, electromagnetic waves having wavelength bands corresponding to depths of the respective light receiving sections are detected at the light receiving sections in accordance with the wavelength dependency of optical absorption coefficient of a semiconductor substrate material, and signal charges are generated, wherein the plurality of pixel sections are separated by impurity diffusion layers for pixel separation, wherein transfer paths for transferring the signal charges from the light receiving sections in each pixel section are provided on one surface side of the semiconductor substrate, and the electromagnetic wave is incident upon the light receiving sections on an other surface side of the semiconductor substrate, the other surface side is the opposite side of the side where the transfer paths in the semiconductor substrate are provided.

Still preferably, a solid-state image capturing apparatus according to the present invention is a CMOS image sensor or a CCD image sensor.

Still preferably, in a solid-state image capturing apparatus according to the present invention, a lead electrode to the outside is provided at the bottom side of a chip or on the surface of the semiconductor substrate on an electromagnetic wave incidence side.

Still preferably, in a solid-state image capturing apparatus according to the present invention, no planarization film or no on-chip microlens on the planarization film is provided on the surface of the semiconductor substrate on the electromagnetic wave incidence side.

An electronic information device according to the present invention uses a solid-state image capturing apparatus according to the present invention described above as an image input section for an image capturing section thereof, thereby the objective described above being achieved.

Hereinafter, the functions of the present invention having the structures described above will be described.

According to a solid-state image capturing apparatus of the present invention, a plurality of pixel sections (solid-state image capturing devices), each having a plurality of light receiving sections laminated in a depth direction of a semiconductor substrate, are arranged according to a sequence in a direction along a plane of the substrate. For incident light (electromagnetic wave), electromagnetic waves having wavelength bands corresponding to the depths of the respective light receiving sections are detected at the light receiving sections in accordance with the wavelength dependency of optical absorption coefficient of semiconductor substrate material, and signal charges are generated. Therefore, it is possible to enhance the degree of integration in a pixel, and also possible without providing a color filter to separate and detect electromagnetic waves (optical components) having different wavelengths at respective light receiving sections. Pixel sections are electrically separated from each other by impurity diffusion layers.

Impurity diffusion layers (light receiving section diffusion layers), each forming a light receiving section, are formed at an ion implantation step as a light receiving section forming step of performing a plurality of ion implantations at different depths in the depth direction of the semiconductor substrate on the entire semiconductor substrate or on the entire image capturing region (image capturing device region). In addition, impurity diffusion layers for pixel separation (pixel separation section diffusion layers) are formed at a photolithography step as a mask forming step of forming an ion implantation mask having an opening at a location corresponding to a pixel separation section in the semiconductor substrate and at an ion implantation step of performing an ion implantation for the semiconductor substrate via the opening of the ion implantation mask in a pixel separation section forming step. With the steps described above, light receiving section diffusion layers and pixel separation section diffusion layers are formed, and pixel sections, each forming a light receiving section, are electrically separated from each other. Further, it is possible to eliminate a planarization film forming step, a color-filter forming step and an on-chip microlens forming step in a manufacturing process associated with the optical characteristic that is specific to a solid-state image capturing apparatus, and thus it is possible to manufacture the solid-state image capturing apparatus with the same line that is used for another semiconductor device. Therefore, even when another semiconductor device and a solid-state image capturing apparatus are mounted in the same chip module in a mixed manner, it is possible to have an improved conformity in the process.

The ion implantation step of forming a light receiving section diffusion layer can be performed from either the top surface side or the bottom surface side of the semiconductor substrate, and it is performed with an appropriate implantation condition to form a desired light receiving section at a desired depth. Further, the photolithography step of forming an opening for a pixel separation section and the ion implantation step of forming a pixel separation section diffusion layer can be also performed from either the top surface side or the bottom surface side of the semiconductor substrate, and they are performed with an appropriate implantation condition to form a desired pixel separation section diffusion layer.

In addition, according to the solid-state image capturing apparatus of the present invention, transfer paths (transistors and wiring layers) for transferring signal charges from the light receiving sections and the required number of transistors forming circuits associated with the selection and signal output for the respective solid-state image capturing devices (light receiving sections in each pixel), amplification sections, selection sections, reset sections and the like are provided on the surface of the semiconductor substrate, which is the opposite side of the electromagnetic wave incidence side. As such, in a pixel array, light is not deflected by the wiring layers or the transistors in a light path. Thus, there is no need for forming an on-chip microlens to focus the light upon the light receiving sections. Further, since the light focusing efficiency is not decreased, it is possible to have a structure of multi-layered wiring layers, and thus it is possible to mount a high functionality image computational process circuit or the like on the same module chip. Further, there is no need for providing a wiring layer between pixel sections in order to transfer signal charges output from the pixel sections (light receiving sections in a pixel section). Therefore, the resolution of the solid-state image capturing apparatus is not decreased due to the size of area for arranging the wiring layers therein. Since transistors and wiring layers connected to the transistors are provided on the opposite side of the light incidence side with light receiving sections, the degree of freedom for the width of wiring layer and the arrangement of wiring layer and transistor is significantly increased. Thus, it is possible to enhance the degree of integration in a pixel. In addition, in a CMOS image sensor, by providing transistors for amplifying and transferring signal charges from pixel sections on the opposite side of the electromagnetic wave incidence side, it is possible to secure a sufficient size of area for stabilizing the transistor characteristic without decreasing the resolution due to the size of area for arranging the transistors therein. Further, since transfer paths (wiring layers and the required number of transistors that form predetermined circuits including the wiring layers) for transferring signal charges from light receiving sections are provided on the opposite side of the electromagnetic wave incidence side, it is possible to perform an ion implantation for forming light receiving section diffusion layers without a photolithography step performed. Accordingly, it is possible to improve the alignment precision between a light receiving section diffusion layer and a pixel separation section diffusion layer for significantly reducing the variance in performance between pixel sections.

As described above, according to the present invention, there is no need for a photolithography step of implanting ions for forming a light receiving section diffusion layer, which was required in the conventional method for a solid-state image capturing apparatus. Accordingly, it is possible to improve the alignment precision between a light receiving section diffusion layer and a pixel separation diffusion layer for reducing the variance in performance between pixel sections.

In addition, transfer paths for transferring signal charges from light receiving sections are provided on the opposite side of the electromagnetic wave incidence side. As such, in a pixel array, light is not deflected by a wiring layer or a transistor in a light path. Thus, there is no need for providing a color filter or on-chip microlens, both of which were required in the conventional solid-state image capturing apparatus. As a result, it is possible to simplify the steps. Accordingly, it is possible to obtain a solid-state image capturing apparatus having a high sensitivity and high resolution with a reduced variance in performance between pixel sections and with no shading generated. In particular, when the present invention is applied to a CMOS image sensor, there is no need for an advanced miniaturization of a transistor arranged in a pixel, and it is possible to stabilize the transfer characteristic of signal charge and improve the image quality while maintaining a high resolution.

Further, it is possible to eliminate the color-filter forming step and the on-chip microlens forming step that were required in a manufacturing process associated with the optical characteristic specific to a solid-state image capturing apparatus in the conventional method for manufacturing the solid-state image capturing apparatus, and thus it is possible to manufacture the solid-state image capturing apparatus with the same line that is used for another semiconductor device. Therefore, even when another semiconductor device and a solid-state image capturing apparatus are mounted in the same chip module in a mixed manner, it is possible to have an improved conformity in the process and to reduce the cost for manufacturing an electronic information device.

### BRIEF DESCRIPTION OF THE DRAWINGS

FIG. 1 is a longitudinal cross-sectional view schematically showing an exemplary essential structure of solid-state image capturing devices provided in a solid-state image capturing apparatus according to Embodiment 1 of the present invention.

FIG. 2 is a longitudinal cross-sectional view for describing a light receiving section forming step in a solid-state image capturing apparatus manufacturing method in FIG. 1.

FIG. 3 is a longitudinal cross-sectional view for describing a photolithography step for pixel separation section diffusion layer in the solid-state image capturing apparatus manufacturing method in FIG. 1.

FIG. 4 is a longitudinal cross-sectional view for describing a pixel separation section diffusion layer forming step in the solid-state image capturing apparatus manufacturing method in FIG. 1.

FIG. 5 is a longitudinal cross-sectional view for describing a control transistor forming step in the solid-state image capturing apparatus manufacturing method in FIG. 1.

FIG. 6 is a plane view schematically showing an exemplary entire structure of a solid-state image capturing apparatus according to Embodiment 2 of the present invention.

FIG. 7 is a plane view showing a portion of an image capturing region of the solid-state image capturing apparatus in FIG. 6 when the portion of the image capturing region is viewed from a light incidence side.

FIG. 8 is a block diagram schematically showing an exemplary structure of an electronic information device according to Embodiment 3 of the present invention.

FIG. 9 is a longitudinal cross-sectional view schematically showing an exemplary structure of a conventional solid-state image capturing apparatus.

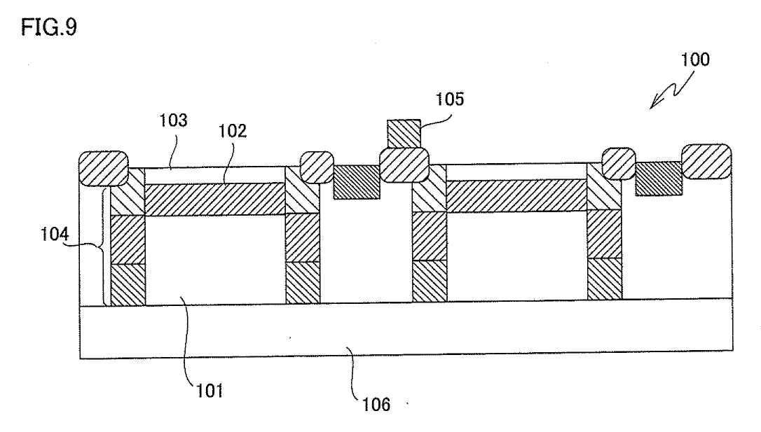

1, 11 solid-state image capturing apparatus

2, 2A, 2B solid-state image capturing device (pixel section)

21 to 23 light receiving section (light receiving section diffusion layer)

21A first light receiving section in pixel section A

21B first light receiving section in pixel section B

22A second light receiving section in pixel section A

22B second light receiving section in pixel section B

23A third light receiving section in pixel section A

23B third light receiving section in pixel section B

3 semiconductor substrate

4 pixel separation section diffusion layer (impurity diffusion layer for pixel separation)

41 ion implantation mask

5 control transistor (transistor)

5A control transistor in pixel section A

5B control transistor in pixel section B

6, 61 to 64 interlayer insulation film

7, 71 to 73 wiring layer

81, 82 via-contact (contact section)

12 row selection signal line and reset signal line

13 column image signal line

14 solid-state image capturing device (pixel section)

15 row selection scan section

16 image signal output section

31 electronic information device

32 memory section

33 display section

34 communication section

### BEST MODE FOR CARRYING OUT THE INVENTION

Hereinafter, Embodiments 1 and 2 of a solid-state image capturing apparatus and a solid-state image capturing apparatus manufacturing method according to the present invention and Embodiment 3 of an electronic information device according to the present invention using the solid-state image capturing apparatus and the solid-state image capturing apparatus manufacturing method for an image capturing section thereof will be described with reference to the accompanying drawings.

### Embodiment 1

Embodiment 1 describes a solid-state image capturing apparatus including, in a depth direction of a substrate, a first light receiving section for detecting an electromagnetic wave having a first wavelength band, a second light receiving section for detecting an electromagnetic wave having a second wavelength band, and a third light receiving section for detecting an electromagnetic wave having a third wavelength band, as a plurality of light receiving sections; and a solid-state image capturing apparatus manufacturing method. In this case, three primary colors of red (R), green (G) and blue (B) can be considered as three colors having different wavelength bands of light, for example. Herein, light having the first wavelength band represents blue light, light having the second wavelength band represents green light, and light having the third wavelength band represents red light.

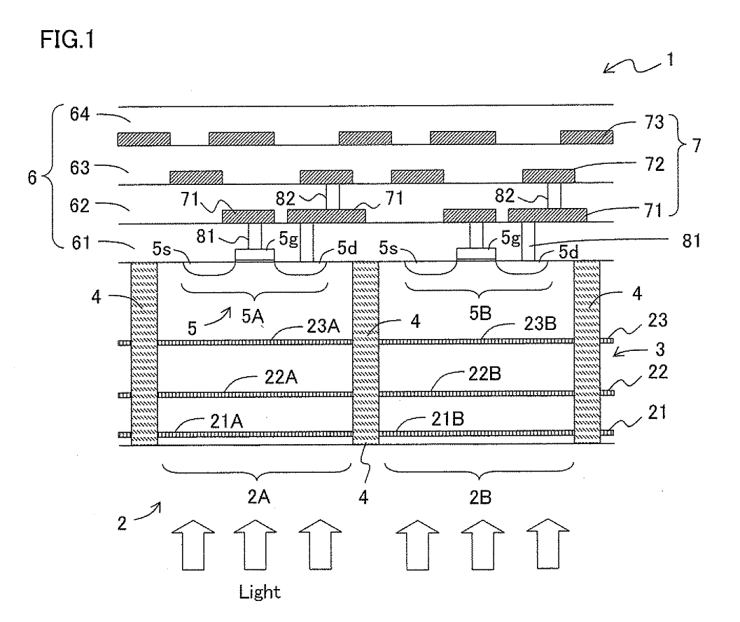

FIG. 1 is a longitudinal cross-sectional view showing an exemplary essential structure of two pixels in a solid-state image capturing apparatus 1 according to Embodiment 1 of the present invention.

In the solid-state image capturing apparatus 1 according to Embodiment 1 in FIG. 1, a plurality of solid-state image capturing devices (pixel sections) 2A, 2B, . . . , each of which is used as a unit pixel section, are repeatedly arranged according to a sequence in a direction along a plane of a semiconductor substrate 3. A plurality of light receiving sections (photoelectric conversion sections; photodiodes each formed due to a semiconductor junction having different conductive types from each other) corresponding to respective colors that are laminated in a depth direction of the semiconductor substrate 3 are provided in each of the pixel sections 2A, 2B.

The semiconductor substrate 3 is a silicon substrate having an epitaxial layer thereon. Light receiving sections are each formed by a photodiode that is formed due to a semiconductor junction having different conductive types from each other. First light receiving sections 21A, 21B for detecting blue light are provided at a depth between 0.1 μm (including 0.1 μm) and 0.4 μm (including 0.4 μm) from the surface of the semiconductor substrate 3 on the light incidence side, second light receiving sections 22A, 22B for detecting green light are provided at a depth between 0.4 μm (including 0.4 μm) and 0.8 μm (including 0.8 μm) from the surface of the semiconductor substrate 3 on the light incidence side, and third light receiving sections 23A, 23B for detecting red light are provided at a depth between 0.8 μm (including 0.8 μm) and 2.5 μm (including 2.5 μm) from the surface of the semiconductor substrate 3 on the light incidence side. By arranging the first light receiving section 21 to the third light receiving section 23 in the depth direction in this manner, it is possible to more accurately detect the color signals of all three primary colors of light in a single pixel. The optimum depth of each of the light receiving sections 2A, 2B is set in accordance with a corresponding wavelength to be detected and the optical absorption coefficient of the semiconductor substrate material. Therefore, the depth ranges described above merely indicate typical values, and thus they are not limited thereto. The light receiving sections each have a flat surface.

The pixel sections 2A, 2B, . . . are electrically separated from each other by pixel separation section diffusion layers 4 provided in the depth direction.

Control transistors 5A, 5B, . . . for controlling the transfer of signal charges from the respective light receiving sections are provided in the pixel sections 2A, 2B, . . . , respectively. The control transistors 5A, 5B, . . . each form a circuit associated with the selection and signal output for the respective pixel sections 2A, 2B, . . . . A source region 5s and a drain region 5d for each of the control transistors 5A, 5B are provided in an impurity diffusion layer well that forms the light receiving section. A gate electrode 5g is provided on the impurity diffusion layer well between the source region 5s and the drain region 5d via a gate insulation film. Multi-layered wiring layers 71 to 73 are provided over the control transistors 5A, 5B, . . . via respective interlayer insulation films 61 to 64. The multi-layered wiring layers 71 to 73 each form a transfer path for signal charge.

The control transistors 5A, 5B, . . . and the wiring layers 71 are electrically connected to each other via via-contacts 81, respectively, provided in the interlayer insulation film 61. The wiring layers 71 and the wiring layers 72 are electrically connected to each other via via-contacts 82, respectively, provided in the interlayer insulation film 62.

In the solid-state image capturing apparatus 1, no planarization film or no on-chip microlens on the planarization film is provided on the surface of the semiconductor substrate 3 on the electromagnetic (light) incidence side.

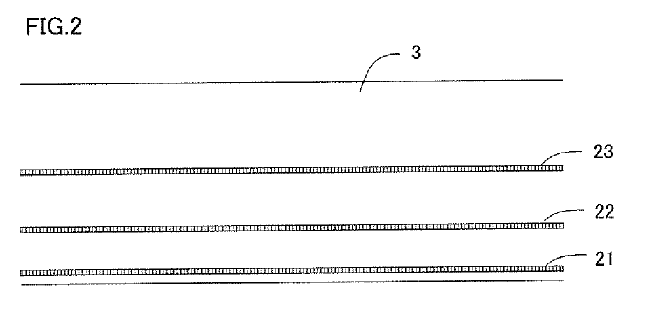

Hereinafter, the solid-state image capturing apparatus manufacturing method for manufacturing the solid-state image capturing apparatus 1 according to Embodiment 1 having the structure described above will be described in detail with reference to FIGS. 2 to 5.

FIGS. 2 to 5 are each an essential longitudinal cross-sectional view for describing a step of manufacturing the solid-state image capturing apparatus 1 according to Embodiment 1.

First, as shown in a light receiving section forming step in FIG. 2, in order to form a desired light receiving section diffusion layer at a desired depth, a plurality of ion implantations is performed at different locations in the depth direction of the semiconductor substrate 3 on the entire semiconductor substrate 3 (or on the entire image capturing region), and the first light receiving section 21 for detecting blue light, the second light receiving section 22 for detecting green light and the third receiving section 23 for detecting red light are sequentially formed. It should be noted that the ion implantation step can be performed either from the side where a transfer path for the semiconductor substrate 3 is formed (the upper side in FIG. 2) or from the side opposite thereto (the lower side in FIG. 2).

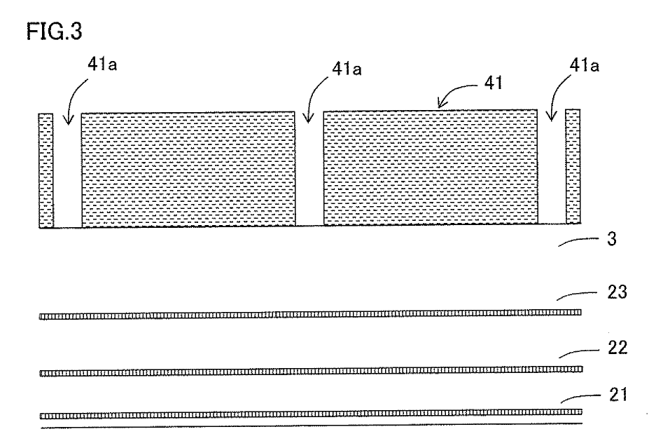

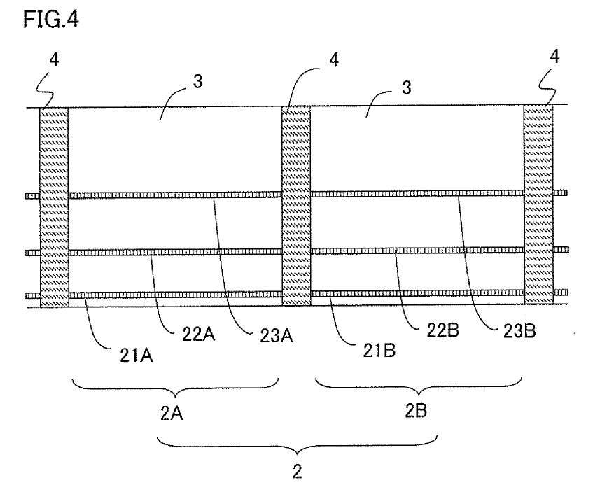

Next, as shown in a mask forming step of a pixel separation section forming step in FIG. 3, a photolithography is performed to form ion implantation masks 41 each having an opening 41a for the ion implantation region (pixel separation section). Further, in the ion implantation step of the pixel separation section forming step, impurity ions are implanted through the openings 41a into the semiconductor substrate 3 using the respective ion implantation masks 41 to form desired pixel separation diffusion layers at desired depths. The pixel separation section diffusion layers 4 (impurity diffusion layers for pixel separation) are each formed like a wall at a location deeper than the light receiving section 23 (23A, 23B) that is provided at the deepest location from the surface of the semiconductor substrate 3 on the electromagnetic wave incidence side. As a result, as shown in FIG. 4, the pixel separation section diffusion layers 4 (impurity diffusion layers for pixel separation) are formed, and pixel sections, for example, the pixel section 2A and the pixel section 2B, are electrically separated from each other by the pixel separation section diffusion layers 4. It should be noted that the photolithography step and the ion implantation step can be performed either from the side where a transfer path for the semiconductor substrate 3 is formed (the upper side in FIG. 3) or from the side opposite thereto (the lower side in FIG. 3).

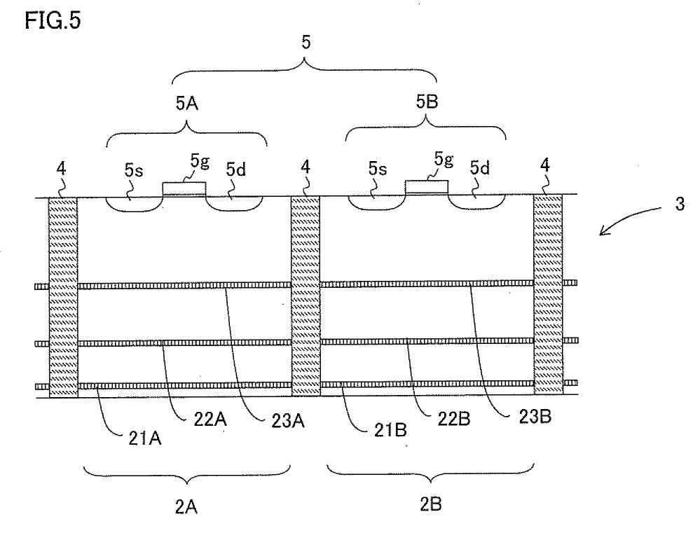

Further, as shown in a transistor forming step in FIG. 5, in a transfer path forming step, the control transistor 5 (5A, 5B), which forms a circuit of transfer path for transferring signal charges from the plurality of light receiving sections 21 to 23 of each pixel section, is formed in the inside and on the impurity diffusion layer well corresponding to the light receiving sections 21 to 23, from the opposite side of the light incidence side where an electromagnetic wave is incident upon the plurality of light receiving sections 21 to 23. It should be noted that the control transistors 5A, 5B, . . . for each controlling the transfer of signal charge of each of the corresponding pixel sections 2A, 2B, . . . are formed using a known technique.

An amplification section for amplifying a signal voltage transferred from each of the light receiving sections 21 to 23 to a charge detection section, a selection section capable of selecting a light receiving section in each pixel section by controlling the reading of a signal amplified by the amplification section, and a reset section for resetting a signal voltage at the charge detection section to a predetermined voltage are configured with transistors 5 in each pixel section.

Thereafter, as shown in FIG. 1, interlayer insulation films 61 to 64 for insulating wirings from each other, wiring layers 71 to 73 each made from a metal material layer, a via-contact 81 which functions as a contact section and which, for example, is provided in the interlayer insulation film 61 between the light receiving sections 21 to 23 and the wiring layer 71 via the transistor 5 (the transistor 5 and the wiring layer 71 are connected with each other via the via-contact 81 to allow the connection between the light receiving sections 21 to 23 and the wiring layer 71), and a via-contact 82 which functions as a contact section and which is provided in the interlayer insulation film 62 between the wiring layer 71 and the wiring layer 72 to electrically connect the wiring layer 71 and the wiring layer 72 to each other are formed using a known technique.

According to the solid-state image capturing apparatus 1 of Embodiment 1 manufactured as described above, the first light receiving sections 21A, 21B, . . . each of which is for detecting an electromagnetic wave having a first wavelength band, the second light receiving sections 22A, 22B, . . . each of which is for detecting an electromagnetic wave having a second wavelength band and the third light receiving sections 23A, 23B, . . . each of which is for detecting an electromagnetic wave having a third wavelength band are sequentially laminated in the depth direction of the semiconductor substrate 3 in the respective pixel sections 2A, 2B, . . . , each of which is a solid-state image capturing device used as a unit pixel section. The control transistors 5A, 5B, . . . and the wiring layers 71 to 73, each made from a metal wiring layer, are provided on the opposite side of the light incidence side in the semiconductor substrate 3, both of which form circuits and transfer paths associated with the selection and signal output for the respective solid-state image capturing devices (pixel sections 2A, 2B, . . . ).

With the structure described above, in the solid-state image capturing apparatus 1 according to Embodiment 1, when an image is captured, light (electromagnetic wave) is incident from the side of the semiconductor substrate 3 where the first light receiving section 21, the second light receiving section 22 and the third light receiving section 23 are formed. For incident light (electromagnetic wave), electromagnetic waves having wavelength bands corresponding to the depths of the respective light receiving sections are detected at the light receiving sections 21 to 23 in accordance with the wavelength dependency of optical absorption coefficient of semiconductor substrate material, and signal charges corresponding to the respective wavelength bands are generated. For example, blue light is detected at the first light receiving section 21, green light is detected at the second light receiving section 22, and red light is detected at the third light receiving section 23. Therefore, it is not necessary to form a color filter, so problems, such as decrease of sensitivity, decrease of resolution and the like which are caused by the provision of color filter, do not occur.

The wiring layers 71 to 73 are provided on the opposite side of the light incidence side in the semiconductor substrate 3. Therefore, the deflection of light by the wiring layers 71 to 73 in a light path does not occur at all, and thus the problem of shading does not occur. In addition, there is no need for changing the light path by an on-chip microlens, and thus there is no need for an on-chip microlens forming step of forming an on-chip microlens.

Further, the pixel sections 2A, 2B, . . . (solid-state image capturing devices) are electrically separated from each other by the pixel separation section diffusion layers 4, and there is no need for a photolithography step of light receiving section diffusion layer forming ion implantation. Accordingly, it is possible to improve the alignment precision between a light receiving section diffusion layer and a pixel separation diffusion layer for significantly reducing the variance in performance between the pixel sections 2A, 2B, . . . .

In Embodiment 1, the first light receiving section 21 for detecting an electromagnetic wave having the first wavelength band, the second light receiving section 22 for detecting an electromagnetic wave having the second wavelength band and the third light receiving section 23 for detecting an electromagnetic wave having the third wavelength band are provided as a plurality of light receiving sections. Alternatively, N number of light receiving sections can be provided as the plurality of light receiving sections, wherein the N number of light receiving sections include a first light receiving section for detecting an electromagnetic wave having a first wavelength band up to an Nth light receiving section for detecting an electromagnetic wave having an Nth wavelength band, where N is a natural number greater than or equal to 2. For example, in the case where a first light receiving section for detecting an electromagnetic wave having a first wavelength band and a second light receiving section for detecting an electromagnetic wave having a second wavelength band are provided, the first light receiving section for detecting white light can be formed by setting the depth of the first light receiving section from the surface of the semiconductor substrate on the light incidence side in a range between 0.2 μm (including 0.2 μm) and 2.0 μm (including 2.0 μm) at the depletion layer, and the second light receiving section for detecting infrared light can be formed by setting the depth of the second light receiving section from the surface of the semiconductor substrate on the light incidence side in a range of 3.0 μm±0.3 μm. Alternatively, a first light receiving section for detecting ultraviolet light can be formed by setting the depth of the first light receiving section from the surface of the semiconductor substrate on the light incidence side in a range between 0.1 μm (including 0.1 μm) and 0.2 μm (including 0.2 μm), and a second light receiving section for detecting white light can be formed by setting the depth of the second light receiving section from the surface of the semiconductor substrate on the light incidence side in a range 0.2 μm (including 0.2 μm) and 2.0 μm (including 2.0 μm) at the depletion layer. Further, in the case where a first light receiving section for detecting an electromagnetic wave having a first wavelength band, a second light receiving section for detecting an electromagnetic wave having a second wavelength band, a third light receiving section for detecting an electromagnetic wave having a third wavelength band and a fourth light receiving section for detecting an electromagnetic wave having a fourth wavelength band are provided as a plurality of light receiving sections, the first light receiving section to the fourth light receiving section for detecting three primary colors and emerald color, respectively, can be formed by setting the depth of the first light receiving section from the surface of the semiconductor substrate on the light incidence side in a range between 0.1 μm (including 0.1 μm) and 0.4 μm (including 0.4 μm), the depth of the second light receiving section from the surface of the semiconductor substrate on the light incidence side in a range between 0.3 μm (including 0.3 μm) and 0.6 μm (including 0.6 μm), the depth of the third light receiving section from the surface of the semiconductor substrate on the light incidence side in a range between 0.4 μm (including 0.4 μm) and 0.8 μm (including 0.8 μm), and the depth of the fourth light receiving section from the surface of the semiconductor substrate on the light incidence side in a range between 0.8 μm (including 0.8 μm) and 2.5 μm (including 2.5 μm). In this case, a light receiving section may be added, in which a depth of the light receiving section from the surface of the semiconductor substrate on the light incidence side is set to a light receiving section depth corresponding to color light that is intended for accurate representation.

When the light receiving section diffusion layers are formed, a polishing step is provided subsequent to the ion implantation step, and the surface of the semiconductor substrate 3 on the electromagnetic wave incidence side is polished. As a result, it is possible to optimize the distance to each of the light receiving sections. Alternatively, the surface of the semiconductor substrate on the electromagnetic wave incidence side is polished up to the top surface of the light receiving section which is located closest to the surface of the semiconductor substrate 3 on the electromagnetic wave incidence side.

Further, an infrared cut filter may be provided on the surface of the semiconductor substrate 3 on the electromagnetic wave incidence side at an infrared cut filter forming step and/or a support substrate made from a transparent silicon substrate or glass substrate may be provided on the opposite side of the surface of the semiconductor substrate 3 on the electromagnetic wave incidence side to enhance the durability of the semiconductor substrate 3 at a support substrate attachment step.

### Embodiment 2

Embodiment 2 describes an example of a preferred size of a solid-state image capturing device and the number of the solid-state image capturing devices to be effectively arranged.

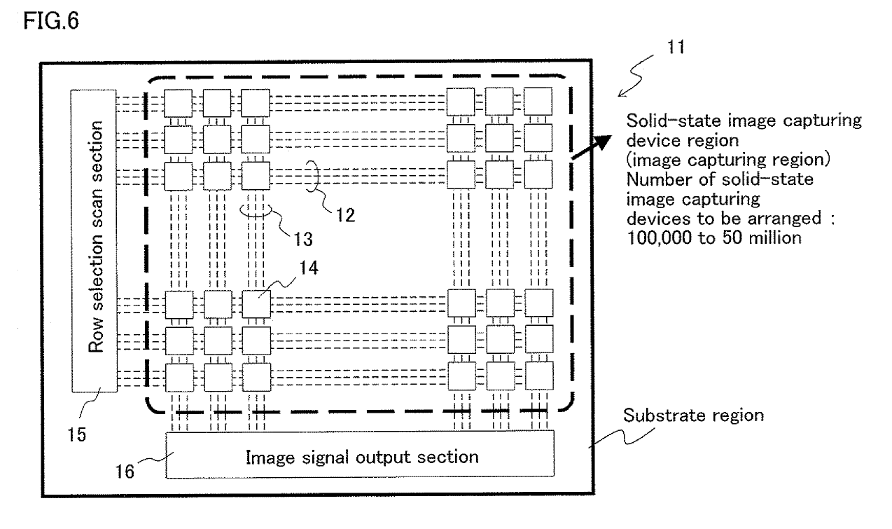

FIG. 6 is a plane view schematically showing an exemplary essential structure of a solid-state image capturing apparatus 11 according to Embodiment 2 of the present invention.

In FIG. 6, the solid-state image capturing apparatus 11 according to Embodiment 2 is a CMOS image sensor. In the solid-state image capturing apparatus 11, three row selection signal lines and reset signal lines 12 and three column image signal lines 13 make up one set, and they are arranged to intersect with each other (at right angles). A plurality of solid-state image capturing devices 14 (which correspond to pixel sections 2 in FIG. 1) are repeatedly arranged (in a matrix) according to a sequence at intersections of both signal lines 12 and 13. The row selection signal lines and reset signal lines 12 and the column image signal lines 13 are connected to the solid-state image capturing devices 14, respectively. The row selection signal lines and reset signal lines 12 are connected to a row selection scan section 15 that is provided at the left end of the substrate. The column image signal lines 13 are connected to an image signal output section 16 that is provided at the lower end of the substrate.

The solid-state image capturing device forming a unit pixel section has a similar structure to those of the pixel sections 2A, 2B, . . . in FIG. 1. The shape of a pixel section of a solid-state image capturing device 14 is square in a plane view, and a length of each side of the solid-state image capturing device 14 is set in a range between 1.0 μm (including 1.0 μm) and 20.0 μm (including 20.0 μm). By setting the length of each side of the solid-state image capturing device 14 within this range, it is possible to improve the sensitivity and the resolution in the solid-state image capturing apparatus 11 in the most effective manner.

Further, the solid-state image capturing devices 14 are arranged in a range between 100,000 pixels (including 100,000 pixels) and 50 million pixels (including 50 million pixels) in the solid-state image capturing apparatus 11. By setting the number of the solid-state image capturing devices 14 in this manner so as to be effectively arranged, it is possible to improve the sensitivity and the resolution of the solid-state image capturing apparatus 11 in the most effective manner.

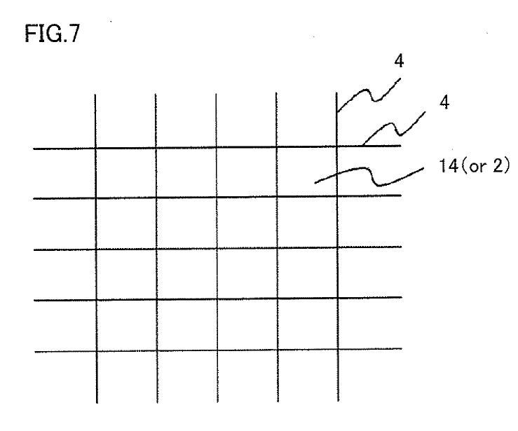

In this case, when the semiconductor substrate is viewed from the surface of the electromagnetic wave incidence side, only pixel separation section diffusion layers 4, each having a predetermined width, are provided in an image capturing region in a lattice in a plane view to separate adjacent solid-state image capturing devices 14 from each other, as shown in FIG. 7. Thus, there is no wiring layer around each of the solid-state image capturing devices 14, and almost the entire image capturing region becomes a light receiving region. Thus, it is possible to cause light to be incident upon the light receiving sections in the most effective manner.

Embodiment 2 has described about the CMOS image sensor. However, the size of a solid-state image capturing device and the number of the solid-state image capturing device to be effectively arranged can be similarly set for a CCD image sensor as well.

### Embodiment 3

Embodiment 3 describes an example of an electronic information device using a solid-state image capturing apparatus according to the present invention as an image input section for an image capturing section thereof.

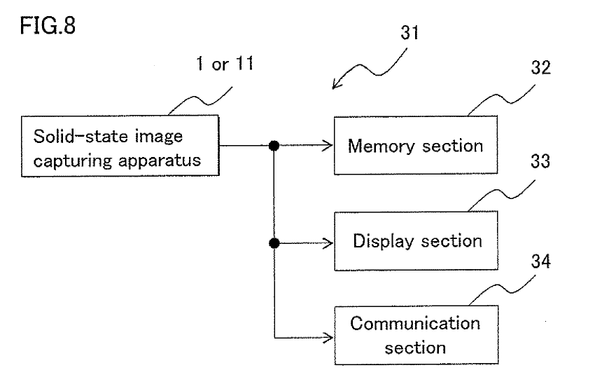

FIG. 8 is a block diagram schematically showing an exemplary essential structure of an electronic information device 31 according to Embodiment 3 of the present invention.

In FIG. 8, the electronic information device 31 according to Embodiment 3 includes: the solid-state image capturing apparatus 1 according to Embodiment 1 or the solid-state image capturing apparatus 11 according to Embodiment 2; a memory section 32 (e.g., recording media) for data-recording a color image signal from the solid-state image capturing apparatus 1 or 11 after a predetermined signal process is performed on the color image signal for recording; a display section 33 functioning as a display section (e.g., liquid crystal display device) for displaying a color image signal from the solid-state image capturing apparatus 1 or 11 on a display screen (e.g., liquid crystal display screen) after a predetermined signal process is performed on the color image signal for display; and a communication section 34 functioning as a communication means (e.g., transmitting and receiving device) for communicating a color image signal from the solid-stage image capturing apparatus 1 or 11 after a predetermined signal process is performed on the color image signal for communication. Further, in addition to the memory section 32, the display section 33 and the communication section 34, an image output device (e.g., printer) may be provided in the electronic information device 31, or alternatively, the electronic information device 31 may include at least one of the memory section 32, the display section 33, the communication section 34 and the image output device.

Any of the following can be considered as the electronic information device 31: a digital camera (e.g., digital video camera, digital still camera), an image input camera (e.g., monitoring camera, door intercom camera, car-mounted camera (car-mounted camera for monitoring the area behind the car), and camera for video-conference telephone), and an image input device (e.g., scanner, facsimile and cell phone device equipped with camera).

Therefore, according to the electronic information device 31 of Embodiment 3, based on a color image signal from the solid-state image capturing apparatus 1 or 11, it is possible to perform a variety of data processes in an excellent manner, such as displaying the color image signal on a display screen in an excellent manner, printing out the color image signal by an image output device on a paper in an excellent manner, communicating the color image signal as communication data in a wired or wireless manner in an excellent manner, and performing a predetermined compression process on the color image signal and storing it in the memory section 32.

As described above, according to Embodiments 1 to 3, a plurality of solid-state image capturing devices (pixel sections 2), each having a plurality of light receiving sections laminated in a depth direction of a semiconductor substrate 3, is repeatedly arranged according to a sequence in a direction along a plane of the substrate. For an incident electromagnetic wave (light), electromagnetic waves having wavelength bands corresponding to the depths of the respective light receiving sections are detected at the light receiving sections in accordance with the wavelength dependency of optical absorption coefficient of semiconductor substrate (e.g., silicon substrate) material, and signal charges are generated. Therefore, it is possible without providing a color filter to separate and detect electromagnetic waves having different wavelengths at respective light receiving sections. Wiring layers 7 for transferring signal charges from the light receiving sections and the required number of transistors 5 are provided on the opposite side of the electromagnetic wave incidence side. As such, in a pixel array, light is not deflected by the wiring layers 7 or the transistors 5 in a light path. Thus, there is no need for forming an on-chip microlens to focus the light upon the light receiving sections. Accordingly, it is possible to obtain a solid-state image capturing apparatus 1 or 11 having a high sensitivity and high resolution with no color filter, no on-chip microlens, or no step of manufacturing the color filter and on-chip microlens required and with no shading generated. Further, since transfer paths (wiring layers 7) for transferring signal charges from light receiving sections and the required number of transistors 5 that form predetermined circuits are provided on the opposite side of the electromagnetic wave incidence side, it is possible to perform an ion implantation for forming light receiving section diffusion layers without a photolithography step performed. Accordingly, it is possible to obtain a solid-state image capturing apparatus having an improved alignment precision between a light receiving section diffusion layer and a pixel separation diffusion layer and also having a reduced variance in performance between pixel sections.

In Embodiments 1 to 3, three light receiving sections are provided at respective predetermined depths of the semiconductor substrate 3 in a depth direction thereof so as to correspond to the wavelengths of three colors of light. However, the present invention is not limited to this. Alternatively, a plurality of light receiving sections can be provided at respective predetermined depths of the semiconductor substrate 3 in a depth direction thereof so as to correspond to the wavelengths of a plurality of colors of light. In view of the color resolution, it is preferable to detect a multiple number of colors, yet the number of manufacturing steps increases as the number of light receiving sections increases.

In addition, although not shown in Embodiments 1 to 3, each of the light receiving sections is electrically connected to the control transistor 5 and the reading circuit, and a signal charge from a desired pixel can be read at a desired timing.

Further, as an example, a single control transistor 5 is provided over each pixel in Embodiments 1 to 3. However, needless to say, the required number of control transistors 5 may be provided depending on the necessity of circuits.

Further, Embodiments 1 to 3 have each described the case, in which three layers of metal wirings 71 to 73 are provided, as an example. However, the present invention is not limited to this. The present invention can be applied to a structure having multi-layered wirings 7 having a number other than 3. Alternatively, the present invention can be applied to a structure having one layer of metal wiring 7.

Further, Embodiments 1 to 3 have not made any particular description about the following. However, a lead electrode to the outside can be provided at the bottom side of a chip or on the surface of a semiconductor substrate on the light incidence side.

The distances to the light receiving sections are, for example, 0.1 μm (including 0.1 μm) and 0.4 μm (including 0.4 μm) from the surface of the semiconductor substrate on the light incidence side to the first light receiving section 21, 0.4 μm (including 0.4 μm) and 0.8 μm (including 0.8 μm) from the surface of the semiconductor substrate on the light incidence side to the second light receiving section 22 and 0.8 μm (including 0.8 μm) and 2.5 μm (including 2.5 μm) from the surface of the semiconductor substrate on the light incidence side to the third light receiving section 23. The locations of these light receiving sections 21 to 23 are closer to the surface of the solid-state image capturing device on the light incidence side compared to the conventional technique, which provides a planarization film on each of the light receiving sections 21 to 23 and also provides a color filter and/or an on-chip microlens on the planarization film. Hence, there is no need for providing a planarization film on the light receiving sections 21 to 23 or providing an on-chip microlens on the planarization film. In other words, the present invention has a structure in which a planarization film is not provided on the surface of a semiconductor substrate 3 on the light (electromagnetic wave) incidence side and an on-chip microlens is not provided on the planarization film. Needless to say, each of the light receiving sections 21 to 23 has a flat surface.

As described above, the present invention is exemplified by the use of its preferred Embodiments 1 to 3. However, the present invention should not be interpreted solely based on Embodiments 1 to 3 described above. It is understood that the scope of the present invention should be interpreted solely based on the claims. It is also understood that those skilled in the art can implement equivalent scope of technology, based on the description of the present invention and common knowledge from the description of the detailed preferred Embodiments 1 to 3 of the present invention. Furthermore, it is understood that any patent, any patent application and any references cited in the present specification should be incorporated by reference in the present specification in the same manner as the contents are specifically described therein.

### INDUSTRIAL APPLICABILITY

According to the present invention, in a field of: a solid-state image capturing apparatus manufacturing method for manufacturing a solid-state image capturing apparatus (e.g., CMOS image sensor, CCD image sensor and the like), in particular, a solid-state image capturing apparatus using a process of separating and detecting light (electromagnetic wave) having different wavelengths by using a plurality of light receiving sections that are laminated in a depth direction of a semiconductor substrate; a solid-state image capturing apparatus manufactured using the solid-state image capturing apparatus manufacturing method; and an electronic information device (e.g., digital camera (digital video camera, digital still camera), a variety of image input cameras, scanner, facsimile, cell phone device equipped with camera and the like) using the solid-state image capturing apparatus as an image input device for an image capturing section thereof, there is no need for a photolithography step of implanting ions for forming a light receiving section diffusion layer, which was required in the conventional method for a solid-state image capturing apparatus. Accordingly, it is possible to improve the alignment precision between a light receiving section diffusion layer and a pixel separation diffusion layer for reducing the variance in performance between pixel sections.

In addition, in a pixel array, light is not deflected by a wiring layer or a transistor in a light path. Thus, there is no need for providing a color filter or on-chip microlens, both of which were required in the conventional solid-state image capturing apparatus. As a result, it is possible to simplify the steps. Accordingly, it is possible to obtain a solid-state image capturing apparatus having a high sensitivity and high resolution with a reduced variance in performance between pixel sections and with no shading generated. In particular, when the present invention is applied to a CMOS image sensor, there is no need for an advanced miniaturization of a transistor arranged in a pixel, and it is possible to stabilize the transfer characteristic of signal charge and improve the image quality while maintaining a high resolution.

Further, it is possible to eliminate the color-filter forming step and the on-chip microlens forming step that were required in a manufacturing process associated with the optical characteristic specific to a solid-state image capturing apparatus in the conventional method for manufacturing the solid-state image capturing apparatus, and thus it is possible to manufacture the solid-state image capturing apparatus with the same line that is used for another semiconductor device. Therefore, even when another semiconductor device and a solid-state image capturing apparatus are mounted in the same chip module in a mixed manner, it is possible to have an improved conformity in the process and to reduce the cost for manufacturing an electronic information device.

1-41. (canceled)

42. A solid-state image capturing apparatus manufacturing method comprising:
a light receiving section forming step of forming a plurality of impurity diffusion layers laminated in a depth direction of a semiconductor substrate as a plurality of light receiving sections by performing a plurality of ion implantations on an entire predetermined region of the semiconductor substrate;
a pixel separation section forming step of forming impurity diffusion layers for pixel separation in the predetermined region to separate pixel sections; and
a transfer path forming step of forming transfer paths for transferring signal charges from the plurality of light receiving sections, the transfer paths being formed on an opposite side of an electromagnetic wave incidence side where an electromagnetic wave is incident upon the plurality of light receiving sections.

43. A solid-state image capturing apparatus manufacturing method according to claim 42, wherein the entire predetermined region of the semiconductor substrate is an entire semiconductor substrate or an entire image capturing region of the semiconductor substrate.

44. A solid-state image capturing apparatus manufacturing method according to claim 42, wherein the pixel separation section forming step includes:
a mask forming step of forming an ion implantation mask having an opening at a location corresponding to a pixel separation section in the semiconductor substrate; and
an ion implantation step of performing an ion implantation for the semiconductor substrate via the opening of the ion implantation mask.

45. A solid-state image capturing apparatus manufacturing method according to claim 44, wherein the mask forming step is a photolithography step.

46. A solid-state image capturing apparatus manufacturing method according to claim 42, wherein an ion implantation is performed from a surface of an opposite side of a side surface where the transfer paths are formed at at least one of the light receiving section forming step and the pixel separation section forming step.

47. A solid-state image capturing apparatus manufacturing method according to claim 44, wherein an ion implantation is performed from a surface of an opposite side of a side surface where the transfer paths are formed at at least one of the light receiving section forming step and the pixel separation section forming step.

48. A solid-state image capturing apparatus manufacturing method according to claim 42, wherein an ion implantation is performed from a side surface where the transfer paths are formed at at least one of the light receiving section forming step and the pixel separation section forming step.

49. A solid-state image capturing apparatus manufacturing method according to claim 44, wherein an ion implantation is performed from a side surface where the transfer paths are formed at at least one of the light receiving section forming step and the pixel separation section forming step.

50. A solid-state image capturing apparatus manufacturing method according to claim 42, wherein the semiconductor substrate is a silicon substrate having an epitaxial layer thereon.

51. A solid-state image capturing apparatus manufacturing method according to claim 42, wherein the light receiving section forming step forms photodiodes as the plurality of light receiving sections, each of the photodiodes being formed due to a semiconductor junction having different conductive types from each other.

52. A solid-state image capturing apparatus manufacturing method according to claim 42, wherein the light receiving section forming step forms an N number of light receiving sections used as the plurality of light receiving sections, wherein the N number of light receiving sections include a first light receiving section for detecting an electromagnetic wave having a first wavelength band up to an Nth light receiving section for detecting an electromagnetic wave having an Nth wavelength band, where N is a natural number greater than or equal to 2.

53. A solid-state image capturing apparatus manufacturing method according to claim 52, wherein the light receiving section forming step forms a first light receiving section for detecting an electromagnetic wave having a first wavelength band and a second light receiving section for detecting an electromagnetic wave having a second wavelength band used as the plurality of light receiving sections.

54. A solid-state image capturing apparatus manufacturing method according to claim 52, wherein the light receiving section forming step forms a first light receiving section for detecting an electromagnetic wave having a first wavelength band, a second light receiving section for detecting an electromagnetic wave having a second wavelength band, and a third light receiving section for detecting an electromagnetic wave having a third wavelength band used as the plurality of light receiving sections.

55. A solid-state image capturing apparatus manufacturing method according to claim 52, wherein the light receiving section forming step forms a first light receiving section for detecting an electromagnetic wave having a first wavelength band, a second light receiving section for detecting an electromagnetic wave having a second wavelength band, a third light receiving section for detecting an electromagnetic wave having a third wavelength band, and a fourth light receiving section for detecting an electromagnetic wave having a fourth wavelength band used as the plurality of light receiving sections.

56. A solid-state image capturing apparatus manufacturing method according to claim 53, wherein the light receiving section forming step forms the first light receiving section to detect white light when a depth of the first light receiving section from the surface of the semiconductor substrate on a light incidence side is in a range between 0.2 μm (including 0.2 μm) and 2.0 μm (including 2.0 μm) at a depletion layer, and forms the second light receiving section to detect infrared light when a depth of the second light receiving section from the surface of the semiconductor substrate on the light incidence side is in a range of 3.0 μm±0.3 μm.

57. A solid-state image capturing apparatus manufacturing method according to claim 53, wherein the light receiving section forming step forms the first light receiving section to detect ultraviolet light when a depth of the first light receiving section from the surface of the semiconductor substrate on a light incidence side is in a range between 0.1 μm (including 0.1 μm) and 0.2 μm (including 0.2 μm), and the second light receiving section to detect white light when a depth of the second light receiving section from the surface of the semiconductor substrate on the light incidence side is in a range 0.2 μm (including 0.2 μm) and 2.0 μm (including 2.0 μm) at a depletion layer.

58. A solid-state image capturing apparatus manufacturing method according to claim 54, wherein the light receiving section forming step forms the first light receiving section, the second light receiving section and the third light receiving section to detect three primary colors, respectively, in which blue light is detected when a depth of the first light receiving section from the surface of the semiconductor substrate on a light incidence side is in a range between 0.1 μm (including 0.1 μm) and 0.4 μm (including 0.4 μm), green light is detected when a depth of the second light receiving section from the surface of the semiconductor substrate on the light incidence side is in a range between 0.4 μm (including 0.4 μm) and 0.8 μm (including 0.8 μm), and red light is detected when a depth of the third light receiving section from the surface of the semiconductor substrate on the light incidence side is in a range between 0.8 μm (including 0.8 μm) and 2.5 μm (including 2.5 μm).

59. A solid-state image capturing apparatus manufacturing method according to claim 55, wherein the light receiving section forming step forms the first light receiving section, the second light receiving section, the third light receiving section and the fourth light receiving section to detect three primary colors and emerald color, respectively, in which blue light is detected when a depth of the first light receiving section from the surface of the semiconductor substrate on a light incidence side is in a range between 0.1 μm (including 0.1 μm) and 0.4 μm (including 0.4 μm), emerald light is detected when a depth of the second light receiving section from the surface of the semiconductor substrate on the light incidence side is in a range between 0.3 μm (including 0.3 μm) and 0.6 μm (including 0.6 μm), green light is detected when a depth of the third light receiving section from the surface of the semiconductor substrate on the light incidence side is in a range between 0.4 μm (including 0.4 μm) and 0.8 μm (including 0.8 μm), and red light is detected when a depth of the fourth light receiving section from the surface of the semiconductor substrate on the light incidence side is in a range between 0.8 μm (including 0.8 μm) and 2.5 μm (including 2.5 μm).

60. A solid-state image capturing apparatus manufacturing method according to claim 56, wherein the light receiving section forming step forms a further light receiving section, in which a depth of the further light receiving section from the surface of the semiconductor substrate on the electromagnetic wave incidence side is set to a light receiving section depth corresponding to color light that is intended for accurate representation.

61. A solid-state image capturing apparatus manufacturing method according to claim 57, wherein the light receiving section forming step forms a further light receiving section, in which a depth of the further light receiving section from the surface of the semiconductor substrate on the electromagnetic wave incidence side is set to a light receiving section depth corresponding to color light that is intended for accurate representation.

62. A solid-state image capturing apparatus manufacturing method according to claim 58, wherein the light receiving section forming step forms a further light receiving section, in which a depth of the further light receiving section from the surface of the semiconductor substrate on the electromagnetic wave incidence side is set to a light receiving section depth corresponding to color light that is intended for accurate representation.

63. A solid-state image capturing apparatus manufacturing method according to claim 59, wherein the light receiving section forming step forms a further light receiving section, in which a depth of the further light receiving section from the surface of the semiconductor substrate on the electromagnetic wave incidence side is set to a light receiving section depth corresponding to color light that is intended for accurate representation.

64. A solid-state image capturing apparatus manufacturing method according to claim 42, wherein the light receiving section is formed to have a flat surface.

65. A solid-state image capturing apparatus manufacturing method according to claim 42, wherein the pixel separation section forming step forms the impurity diffusion layers for pixel separation to have each a predetermined width provided in a lattice in a plane view.

66. A solid-state image capturing apparatus manufacturing method according to claim 42, wherein the pixel separation section forming step forms the impurity diffusion layers for pixel separation, each formed like a wall at a location deeper than the light receiving section that is provided at the deepest location from the surface of the semiconductor substrate on the electromagnetic wave incidence side.

67. A solid-state image capturing apparatus manufacturing method according to claim 65, wherein the pixel separation section forming step forms the impurity diffusion layers for pixel separation, each formed like a wall at a location deeper than the light receiving section that is provided at the deepest location from the surface of the semiconductor substrate on the electromagnetic wave incidence side.

68. A solid-state image capturing apparatus manufacturing method according to claim 65, wherein a length of one side of a pixel section surrounded by the impurity diffusion layers for pixel separation is within a range between 1.0 μm (including 1.0 μm) and 20.0 μm (including 20.0 μm) when viewed from the electromagnetic wave side.

69. A solid-state image capturing apparatus manufacturing method according to claim 68, wherein a pixel section has a squared or rectangular shape when viewed from the electromagnetic wave side.

70. A solid-state image capturing apparatus manufacturing method according to claim 68, wherein the number of solid-state image capturing devices, each corresponding to a single pixel section, to be effectively arranged is set in a range between 100,000 pixels (including 100,000 pixels) and 50 million pixels (including 50 million pixels).

71. A solid-state image capturing apparatus manufacturing method according to claim 69, wherein the number of solid-state image capturing devices, each corresponding to a single pixel section, to be effectively arranged is set in a range between 100,000 pixels (including 100,000 pixels) and 50 million pixels (including 50 million pixels).

72. A solid-state image capturing apparatus manufacturing method according to claim 42, wherein the transfer path forming step forms in each of the plurality of pixel sections:
a circuit for selecting a light receiving section of a particular pixel section among the plurality of pixel sections and for outputting a signal from the selected light receiving section of the particular pixel section, and forms transistors that form the circuit on the opposite side of the semiconductor substrate on the electromagnetic wave incidence side.

73. A solid-state image capturing apparatus manufacturing method according to claim 42, wherein the transfer path forming step forms in each of the plurality of pixel sections:
a circuit for selecting a light receiving section of a particular pixel section among the plurality of pixel sections and for outputting a signal from the selected light receiving section of the particular pixel section, and forms transistors that form the circuit in an impurity diffusion layer well forming the light receiving sections and on the impurity diffusion layer well.

74. A solid-state image capturing apparatus manufacturing method according to claim 72, wherein the transfer path forming step forms in each of the plurality of pixel sections:
a circuit for selecting a light receiving section of a particular pixel section among the plurality of pixel sections and for outputting a signal from the selected light receiving section of the particular pixel section, and forms transistors that form the circuit in an impurity diffusion layer well forming the light receiving sections and on the impurity diffusion layer well.

75. A solid-state image capturing apparatus manufacturing method according to claim 72, wherein the transfer path forming step forms in each of the plurality of pixel sections:
an amplification section for amplifying a signal in accordance with a signal voltage transferred from the light receiving section to a charge detection section,
wherein
the amplification section is configured with a transistor.

76. A solid-state image capturing apparatus manufacturing method according to claim 75, wherein the transfer path forming step forms in each of the plurality of pixel sections:
a selection section capable of selecting a light receiving section in each pixel section by controlling the reading of the signal amplified by the amplification section; and
a reset section for resetting the signal voltage at the charge detection section to a predetermined voltage,
wherein
the selection section and the reset section are each configured with a transistor.

77. A solid-state image capturing apparatus manufacturing method according to claim 42, wherein the transfer path forming step forms the transfer paths with transistors and wiring layers connected to the transistors.

78. A solid-state image capturing apparatus manufacturing method according to claim 72, wherein the transfer path forming step forms the transfer paths with transistors and wiring layers connected to the transistors.

79. A solid-state image capturing apparatus manufacturing method according to claim 77, wherein the transfer path forming step forms a contact section in an interlayer insulation film located between the light receiving section and the wiring layer to electrically connect the light receiving section and the wiring layer.

80. A solid-state image capturing apparatus manufacturing method according to claim 78, wherein the transfer path forming step forms a contact section in an interlayer insulation film located between the light receiving section and the wiring layer to electrically connect the light receiving section and the wiring layer.

81. A solid-state image capturing apparatus manufacturing method according to claim 77, wherein the wiring layers form a multi-layered wiring layer, and the transfer path forming step forms a contact section in an interlayer insulation film located between the wiring layers to electrically connect the wiring layers.

82. A solid-state image capturing apparatus manufacturing method according to claim 78, wherein the wiring layers form a multi-layered wiring layer, and the transfer path forming step forms a contact section in an interlayer insulation film located between the wiring layers to electrically connect the wiring layers.

83. A solid-state image capturing apparatus manufacturing method according to claim 42, further comprising a polishing step of polishing the surface of the semiconductor substrate on the electromagnetic wave side to optimize a distance to each of the plurality of light receiving sections.

84. A solid-state image capturing apparatus manufacturing method according to claim 83, wherein the polishing step polishes the surface of the semiconductor substrate on the electromagnetic wave incidence side to a top surface of the light receiving section which is located closest to the surface of the semiconductor substrate on the electromagnetic wave incidence side.

85. A solid-state image capturing apparatus manufacturing method according to claim 42, further comprising an infrared cut filter forming step of forming an infrared cut filter on the surface of the semiconductor substrate on the electromagnetic wave incidence side.

86. A solid-state image capturing apparatus manufacturing method according to claim 42, further comprising a support substrate attachment step of attaching a support substrate on the opposite side of the surface of the semiconductor substrate on the electromagnetic wave incidence side to enhance the durability of the semiconductor substrate.

87. A solid-state image capturing apparatus manufacturing method according to claim 86, wherein the support substrate is a transparent silicon substrate or a transparent glass substrate.

88. A solid-state image capturing apparatus manufactured according to a solid-state image capturing apparatus manufacturing method according to claim 42.

89. A solid-state image capturing apparatus according to claim 88, wherein a plurality of pixel sections, each having a plurality of light receiving sections laminated in a depth direction of a semiconductor substrate, are arranged according to a sequence in a direction along a plane of the semiconductor substrate; for incident electromagnetic wave, electromagnetic waves having wavelength bands corresponding to depths of the respective light receiving sections are detected at the light receiving sections in accordance with the wavelength dependency of optical absorption coefficient of a semiconductor substrate material, and signal charges are generated,
wherein
the plurality of pixel sections are separated by impurity diffusion layers for pixel separation,
wherein
transfer paths for transferring the signal charges from the light receiving sections in each pixel section are provided on one surface side of the semiconductor substrate, and the electromagnetic wave is incident upon the light receiving sections on an other surface side of the semiconductor substrate, the other surface side is the opposite side of the side where the transfer paths in the semiconductor substrate are provided.

90. A solid-state image capturing apparatus according to claim 88, wherein the solid-state image capturing apparatus is a CMOS image sensor or a CCD image sensor.

91. A solid-state image capturing apparatus according to claim 89, wherein the solid-state image capturing apparatus is a CMOS image sensor or a CCD image sensor.

92. A solid-state image capturing apparatus according to claim 88, wherein a lead electrode to the outside is provided at the bottom side of a chip or on the surface of the semiconductor substrate on an electromagnetic wave incidence side.

93. A solid-state image capturing apparatus according to claim 89, wherein a lead electrode to the outside is provided at the bottom side of a chip or on the surface of the semiconductor substrate on an electromagnetic wave incidence side.

94. A solid-state image capturing apparatus according to claim 88, wherein no planarization film or no on-chip microlens on the planarization film is provided on the surface of the semiconductor substrate on the electromagnetic wave incidence side.

95. A solid-state image capturing apparatus according to claim 89, wherein no planarization film or no on-chip microlens on the planarization film is provided on the surface of the semiconductor substrate on the electromagnetic wave incidence side.

96. An electronic information device using a solid-state image capturing apparatus according to claim 77 as an image input section for an image capturing section thereof.

97. An electronic information device using a solid-state image capturing apparatus according to claim 78 as an image input section for an image capturing section thereof.
